(19) United States
(12) Patent Application Publication
(10) Pub. No.: US 2015/0279923 A1
(43) Pub. Date: Oct. 1, 2015

(54) SEMICONDUCTOR DEVICE

(71) Applicant: Renesas Electronics Corporation, Kawasaki-shi (JP)

(72) Inventors: Makoto UEKI, Kanagawa (JP); Kiyoshi TAKEUCHI, Kanagawa (JP); Takashi HASE, Kanagawa (JP)

(73) Assignee: RENESAS ELECTRONICS CORPORATION

(21) Appl. No.: 14/661,043

(22) Filed: Mar. 18, 2015

(30) Foreign Application Priority Data
Mar. 26, 2014 (JP) 2014-062937

(51) Int. Cl. H01L 49/02; H01L 23/532; H01L 27/06; H01L 23/522

(52) U.S. Cl. CPC H01L 28/65; H01L 23/5226; H01L 23/53242; H01L 23/53257; H01L 28/60; H01L 27/0629

(57) ABSTRACT

To provide a semiconductor device having less variation in characteristics. The semiconductor device is equipped with a plug formed in an interlayer insulating film, a lower electrode provided on the plug and to be coupled to the plug, a middle layer provided on the lower electrode and made of a metal oxide, and an upper electrode provided on the middle layer. The middle layer has a layered region contiguous to the lower electrode and the upper electrode. At least a portion of the layered region does not overlap with the plug. At least a portion of the plug does not overlap with the layered region.

### CROSS-REFERENCE TO RELATED APPLICATIONS

The disclosure of Japanese Patent Application No. 2014-062937 filed on Mar. 26, 2014 including the specification, drawings, and abstract is incorporated herein by reference in its entirety.

### BACKGROUND

The present invention relates to a semiconductor device, for example, a technology applicable to a semiconductor device having a memory element.

The semiconductor device is sometimes equipped with, for example, a memory element. For example, Patent Documents 1 to 3 and Non-patent Document 1 describe a technology related to a variable resistance element (ReRAM (resistance random access memory)) which is a memory element.

Patent Document 1 describes a variable resistance element comprised of a ground side electrode made of a transition metal, a positive side electrode made of a noble metal or a noble metal oxide, and a transition metal oxide film placed between the ground side electrode and the positive side electrode. Patent Document 2 describes a variable resistance element equipped with a variable resistance layer equipped with a first region containing a first oxygen-deficient type transition metal oxide having a composition represented by MOₓ and a second region containing a second oxygen-deficient type transition metal oxide having a composition represented by MO_{y} (x<y).

Patent Document 3 describes a variable resistor for nonvolatile memory equipped with a variable resistance layer provided on the surface of a first wiring layer, an interlayer insulating film provided on the first wiring layer, and a plug metal provided in the interlayer insulating film and to be coupled to the variable resistance layer. Non-patent Document 1 shows investigation results relating to ReRAM using WOₓ.

### PATENT DOCUMENTS

[Patent Document 1] WO2008/075471
[Patent Document 2] WO2010/021134
[Patent Document 3] Japanese Patent Laid-Open No. 2009-117668

### Non-Patent Document

[Non-patent Document 1]
Tech. Dig. IEEE IEDM2010, pp. 440-443

### SUMMARY

A multilayer wiring structure configuring a semiconductor device is sometimes equipped with an MIM (metal insulator metal) structure obtained by successively stacking a lower electrode, a middle layer made of a metal oxide, and an upper electrode. In such a semiconductor device, the thickness of an insulating layer configuring the MIM structure may become uneven by the plug- or wiring-induced irregularities of a wiring layer located below the MIM structure. In this case, semiconductor devices thus obtained may have variation in characteristics. Another problem and novel features will be apparent from the description herein and accompanying drawings.

According to one embodiment, a semiconductor device has a lower electrode, an upper electrode, and a middle layer provided between the lower electrode and the upper electrode and having a layered region contiguous to the lower electrode and the upper electrode. At least a portion of the layered region does not overlap with a plug located below the lower electrode and at least a portion of the plug does not overlap with the layered region.

According to the one embodiment, semiconductor devices having less variation in characteristics can be provided.

### BRIEF DESCRIPTION OF THE DRAWINGS

FIG. 1 is a cross-sectional view showing a semiconductor device according to First Embodiment;

FIG. 2 is a plan view showing the semiconductor device shown in FIG. 1;

FIG. 3 is a schematic plan view showing the semiconductor device according to this embodiment,

FIG. 4 is a cross-sectional view showing a modification example of the semiconductor device shown in FIG. 1;

FIG. 5 is a plan view showing the semiconductor device shown in FIG. 4;

FIG. 6 is a cross-sectional view showing another modification example of the semiconductor device shown in FIG. 1;

FIGS. 7A and 7B show cross-sectional views showing a method of manufacturing the semiconductor device shown in FIG. 1;

FIGS. 8A and 8B show another cross-sectional views showing the method of manufacturing the semiconductor device shown in FIG. 1;

FIGS. 9A and 9B show further cross-sectional views showing the method of manufacturing the semiconductor device shown in FIG. 1;

FIG. 10 is a cross-sectional view showing a semiconductor device according to Second Embodiment;

FIG. 11 is a cross-sectional view showing a modification example of the semiconductor device shown in FIG. 10;

FIG. 12 is a cross-sectional view showing another modification example of the semiconductor device shown in FIG. 10;

FIG. 13 is a cross-sectional view showing a semiconductor device according to Third Embodiment;

FIGS. 14A and 14B show cross-sectional views showing a method of manufacturing the semiconductor device shown in FIG. 13;

FIGS. 15A and 15B show another cross-sectional views showing the method of manufacturing the semiconductor device shown in FIG. 13;

FIGS. 16A and 16B show further cross-sectional views showing the method of manufacturing the semiconductor device shown in FIG. 13;

FIG. 17 is a cross-sectional view showing a semiconductor device according to Fourth Embodiment; and

FIG. 18 is a cross-sectional view showing a modification example of the semiconductor device shown in FIG. 17.

### DETAILED DESCRIPTION

Embodiments will hereinafter be described referring to drawings. In all the drawings, like constituents will be identified by like reference numerals and descriptions on them will be omitted as needed.

### First Embodiment

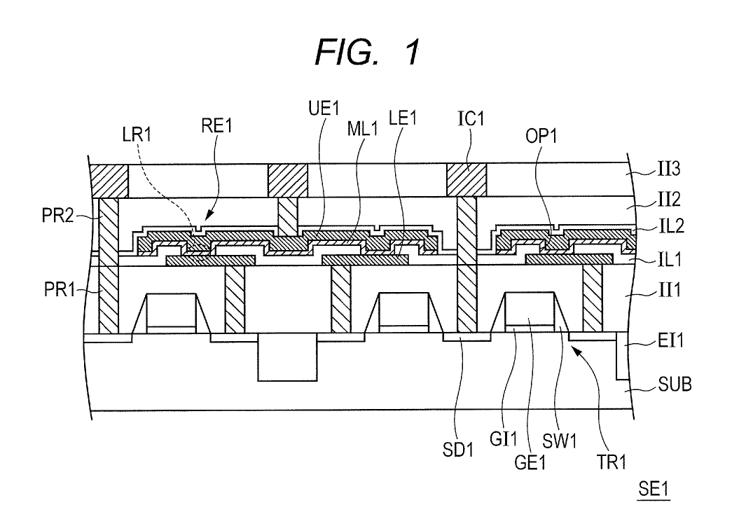

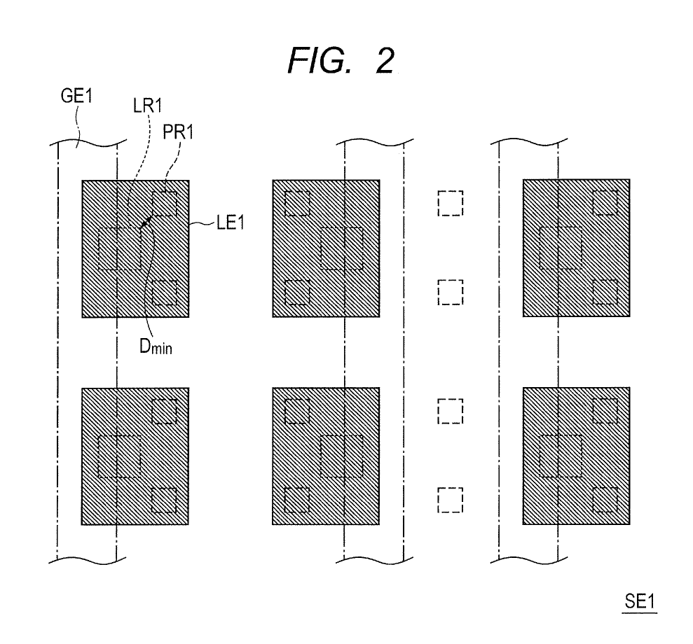

FIG. 1 is a cross-sectional view showing a semiconductor device SE1 according to First Embodiment. FIG. 2 is a plan view showing the semiconductor device SE1 shown in FIG. 1. FIG. 2 shows the positional relationship among a lower electrode LE1, a layered region LR1, a plug PR1, and a gate electrode GE1.

The semiconductor device SE1 according to the present embodiment is equipped with a plug PR1, a lower electrode LE1, a middle layer ML1, and an upper electrode UE1. The plug PR1 is formed in an interlayer insulating film II1. The lower electrode LE1 is provided on the plug PR1 and is coupled to the plug PR1. The middle layer ML1 is provided on the lower electrode LE1 and is composed of a metal oxide. The upper electrode UE1 is provided on the middle layer ML1. The middle layer ML1 has a layered region LR1 contiguous to the lower electrode LE1 and the upper electrode UE1. At least a portion of the layered region LR1 does not overlap with the plug PR1. At least a portion of the plug PR1 does not overlap with the layered region LR1.

As described above, when an MIM structure configuring a memory element has therebelow a plug, the thickness of a middle layer may become uneven due to irregularities formed by the plug. In particular, a plug composed of W may have, at the center thereof, a W-unburied region (seam) and irregularities attributable to this seam may affect the middle layer of the MIM structure. In the semiconductor device SE1 according to the present embodiment, at least a portion of the layered region LR1 does not overlap with the plug PR1 located below the lower electrode LE1 and at the same time, at least a portion of the plug PR1 does not overlap with the layered region LR1. In short, the layered region LR1 of the middle layer ML1 which region is to configure a memory element is formed so as to shift the plane position thereof from a position overlapping with the plug PR1. This makes it possible to reduce the influence of the irregularities due to the plug PR1 on the layered region LR1, compared with the case where the whole layered region LR1 overlaps with the plug PR1 or the whole plug PR1 overlaps with the layered region LR1. This therefore leads to improvement in uniformity of the thickness of the middle layer ML1 in the layered region LR1. According to the present embodiment, therefore, the semiconductor device SE1 having less variation in the characteristics can be provided.

The configuration of the semiconductor device SE1 according to the present embodiment and a method of manufacturing the semiconductor device 5E1 will hereinafter be described in detail.

First, the configuration of the semiconductor device SE1 will be described. The semiconductor device SE1 is equipped with a memory element ME1 having an MIM structure obtained by successively stacking the lower electrode LE1, the middle layer ML1, and the upper electrode UE1. In the present embodiment, as shown in FIG. 1, the MIM structure is comprised of the layered region LR1 of the middle layer ML1, a portion of the lower electrode LE1 contiguous to the layered region LR1, and a portion of the upper electrode UE1 contiguous to the layered region LR1. The layered region LR1 is a region of the middle layer ML1 having a lower surface contiguous to the lower electrode LE1 and an upper surface contiguous to the upper electrode UE1. The semiconductor device SE1 according to the present embodiment is comprised of, for example, a substrate SUB and a multilayer wiring structure formed on the substrate SUB. In this case, the memory element ME1 can be formed, for example, in any of the wiring layers of the multilayer wiring structure.

The semiconductor device SE1 can be equipped with, for example, a resistance variable element as the memory element ME1 having an MIM structure. In this case, the middle layer ML1 functions as a resistance variable layer. The resistance variable element is turned ON or OFF by applying a voltage between the upper electrode UE1 and the lower electrode LE1 and thereby changing the resistance of the middle layer ML1. The resistance variable element may be either a uni-polar type or a bi-polar type. In the present embodiment, either of a uni-polar type and a bi-polar type can be selected, for example, by properly selecting respective materials configuring the lower electrode LE1, the middle layer ML1, and the upper electrode UE1.

In the memory element ME1 which is a resistance variable element, conduction path forming processing called “forming” is performed first after a device is manufactured. In this processing, a voltage is applied between the lower electrode LE1 and the upper electrode UE1 to form a conduction path called “filament” inside the middle layer ML1. The write operation to the memory element ME1 is effected by applying a voltage between the lower electrode LE1 and the upper electrode UE1 to cause conduction or scission of the filament and thereby changing the resistance of the middle layer ML1.

In the present embodiment, the memory element ME1 having the MIM structure is not limited to a resistance variable element but it may be, for example, another element such as DRAM (dynamic random access memory). An appropriate kind of the memory element ME1 having the MIM structure can be selected as needed by properly selecting the material or structure of the lower electrode LE1, upper electrode UE1, and middle layer ML1 configuring the MIM structure.

In the example shown in FIG. 1, the memory element ME1 is coupled to, for example, a transistor TR1. As a result, a unit cell comprised of the memory element ME1 and the transistor TR1 is formed. In the semiconductor device SE1, a plurality of the unit cells can be arranged, for example, in array. As the transistor TR1, for example, an FET (field effect transistor) manufactured by a typical silicon process can be used.

The transistor TR1 is provided, for example, on a substrate SUB. The substrate SUB is, for example, a silicon substrate or a compound semiconductor substrate. As shown in FIG. 1, for example, a plurality of transistors TR1 may be provided on the substrate SUB. The substrate SUB can be provided with an element isolation region EI1 for isolating, for example, the transistor TR1 from another element.

The transistor TR1 shown in FIG. 1 is equipped with, for example, a gate insulating film GI1 provided on the substrate SUB, a gate electrode GE1 provided on the gate insulating film GI1, a sidewall SW1 provided on the sidewall of the gate electrode GE1, and a source•drain region SD1 provided in the substrate SUB. The gate insulating film GI1 is made of, for example, a silicon oxide film. The gate electrode GE1 is made of, for example, a polycrystalline silicon film. Materials of the gate insulating film GI1 and the gate electrode GE1 are not limited to the above-mentioned ones but can be selected from various materials according to the use.

The substrate SUB has thereon, for example, an interlayer insulating film II1 so as to cover the transistor TR1. The interlayer insulating film Ill has therein the plug PR1. The plug PR1 is coupled to, for example, the source•drain region SD1 of the transistor TR1 and configures a source•drain contact plug. The plug PR1 is made of, for example, W.

The interlayer insulating film Ill has thereon the lower electrode LE1. The lower electrode LE1 is provided on the interlayer insulating film Ill and on the plug PR1 so as to bring it into contact with the upper end of the plug PR1. In the example shown in FIG. 1, the lower electrode LE1 is electrically coupled to the source•drain region SD1 of the transistor TR1 via the plug PR1. In the present embodiment, a plurality of the lower electrodes LE1 may be provided so as to be separated from each other. This enables formation of a plurality of the memory elements ME1. In this case, the lower electrodes LE1 are each electrically coupled to the source•drain region SD1 of the transistor TR1 via respectively different plugs PR1.

The lower electrode LE1 is provided so that, for example, a portion of the lower electrode LE1 and the gate electrode GE1 of the transistor TR1 to be coupled thereto via the plug PR1 overlap with each other in plan view. This makes it possible to suppress an increase in the area of the semiconductor device SE1 even when the plane position of the layered region LR1 is shifted from a position overlapping with the plug PR1. The lower electrode LE1 is formed, for example, so as to cover the whole upper end of the plug PR1.

The lower electrode LE1 contains, for example, a first metal material. Examples of the first metal material include Ru, Pt, Ti, W, and Ta, and alloys containing two or more of them. The lower electrode containing such a material can actualize a memory element ME1 having excellent operation performance. Such an advantage becomes more marked when the memory element ME1 is a resistance variable element. The lower electrode LE1 may contain an oxide or nitride of the above-mentioned first metal material. The lower electrode LE1 may have a stacked structure obtained by stacking a plurality of electrode layers composed of respectively different metal materials. The thickness of the lower electrode LE1 can be set at, for example, 3 nm or more but not more than 50 nm. By setting the thickness of the lower electrode LE1 equal to or more than the lower limit, the lower electrode LE1 can function fully as an electrode configuring a memory element. On the other hand, the lower electrode LE1 having a thickness equal to or less than the upper limit can have improved processability at the time of patterning. In addition, the lower electrode LE1 can be thinned fully, which can contribute to improvement in filling, with an interlayer insulating film, a step difference generated between a memory element formation region and another region. This enables manufacture of a more stable semiconductor device.

The interlayer insulating film Ill and the lower electrode LE1 have thereon, for example, an insulating layer IL1. The insulating layer IL1 has an opening portion OP1 located on the lower electrode LE1 and exposing the lower electrode LE1 at the lower end of the insulating layer. The middle layer ML1 is provided, as described later, on the insulating layer IL1 and can be brought into contact with the lower electrode LE1 at the opening portion OP1. In this case, the layered region LR1 of the middle layer ML1 is located in the opening portion OP1.

The insulating layer IL1 is made of SiN, SiON, SiO₂, or SiCN, or a stacked film thereof.

The insulating layer IL1 is provided so that, for example, at least a portion of the opening portion OP1 does not overlap with the plug PR in plan view and at least a portion of the plug PR1 does not overlap with the opening portion OP1 in plan view. This makes it possible to actualize a semiconductor device SE1 having a configuration in which at least a portion of the layered region LR1 does not overlap with the plug PR1 and at the same time at least a portion of the plug PR1 does not overlap with the layered region LR1.

The insulating layer IL1 can be provided so that, for example, at least a portion of the opening portion OP1 overlaps with the gate electrode GE1 of the transistor TR1 to which the lower electrode LE1 exposed below the opening portion OP1 is coupled. The layered region LR1 can therefore be placed so that the layered region LR1 overlaps with the gate electrode GE1 of the transistor TR1. This contributes to downsizing of the semiconductor device SE1.

The insulating layer IL1 has thereon the middle layer ML1. The middle layer ML1 is provided, for example, on the insulating layer IL1 and on the lower electrode LE1 exposed in the opening portion OP1. The middle layer ML1 is therefore contiguous to the lower electrode LE1 in the opening portion OP1. On the other hand, a portion of the middle layer ML1 located outside the opening portion OP1 is provided on the lower electrode LE1 via the insulating layer IL1 so that it is not contiguous to the lower electrode LE1.

As shown in FIG. 1, the middle layer ML1 may be provided so that one middle layer ML1 is contiguous to two lower electrodes LE1 adjacent to each other. In this case, two memory elements ME1 can be formed using one middle layer ML1. In addition, a voltage can be applied to the upper electrode side of two memory elements ME1 adjacent to each other by using one plug PR2.

The middle layer ML1 contains, for example, a second metal material. This means that the middle layer ML1 is made of a metal oxide obtained by oxidizing the second metal material. In the present embodiment, as the middle layer ML1, for example, Ta₂O₅, a stacked film of Ta₂O₅ and TiO₂, ZrO₂, a stacked film of ZrO₂ and Ta₂O₅, NiO, SrTiO₃, SrRuO₃, Al₂O₃, La₂O₃, HfO₂, Y₂O₃, or V₂O₅ can be used. By using the middle layer made of the above-mentioned material, the memory element ME1 can have improved operation performance. Such an advantage becomes more marked when the memory element ME1 is a resistance variable element. Alternatively, as the middle layer ML1, oxygen-deficient metal oxides, that is, metal oxides having an oxygen content stoichiometrically smaller than that of the above-mentioned metal oxides may be used. This enables reduction in operation voltage of the memory element ME1. Such an advantage is more marked when the memory element ME1 is a resistance variable element. The second metal material can be made different from, for example, the first metal material contained in the lower electrode LE1. This makes it possible to select the material configuring the middle layer ML1 without being limited by the material of the lower electrode LE1. The memory element ME1 having improved operation performance can therefore be obtained.

The thickness of the middle layer ML1 can be set at, for example, 1.5 nm or more but not more than 30 nm. By adjusting the thickness of the middle layer ML1 to the lower limit or more, a sufficient insulation property can be secured before forming processing, which can contribute to achieve more stable forming processing. On the other hand, by adjusting the thickness of the middle layer ML1 to not more than the upper limit, on-state resistance can be reduced and improvement in read rate and power reduction can be achieved. The resulting memory element ME1 can therefore have well-balanced reliability and operation performance. In addition, by setting the thickness of the middle layer ML1 to not more than the upper limit, the middle layer ML1 can be made sufficiently thin. This can contribute to improvement in patterning processing or improvement in filling, with an interlayer insulating film, a step difference generated between a memory element formation region and another region. Even when such a thin film is used as the middle layer ML1, the middle layer ML1 actualized in the present embodiment is uniform.

The middle layer ML1 has thereon the upper electrode UE1. The upper electrode UE1 is provided on at least a portion of the middle layer ML1 contiguous to the lower electrode LE1 so as to be brought into contact with this portion. The middle layer ML1 therefore has the layered region LR1 contiguous to the lower electrode LE1 and the upper electrode UE1. In the example shown in FIG. 1, the upper electrode UE1 is provided so as to be contiguous to the middle layer ML1 at least in the opening portion OP1 or on the opening portion OP1. Therefore, the opening portion OP1 has therein the layered region LR1. As described above, the lower electrode LE1, the middle layer ML1, and the upper electrode UE1 are provided so that at least a portion of the layered region LR1 does not overlap with the plug PR1 and at least a portion of the plug PR1 does not overlap with the layered region LR1. This makes it possible to improve the uniformity of the thickness of the middle layer ML1 and thereby provide a semiconductor device having less variation in the characteristics thereof. In the present embodiment, the layered region LR1 is provided more preferably so as not to overlap with the center of the plug PR1 in plan view. When the plug PR1 is made of W, the plug PR1 may have, at the center thereof, an unfilled region (seam) with W. By preventing the layered region LR1 from overlapping with the center of the plug PR1, an influence of the irregularities due to the seam on the middle layer ML1 can be suppressed.

The upper electrode UE1 is provided so as to have, for example, a shape similar to that of the middle layer ML1 in plan view. In this case, the upper electrode UE1 and the middle layer ML1 can be processed simultaneously, which facilitates the manufacturing process. The upper electrode UE1 may however have a plane shape different from that of the middle layer ML1.

When one middle layer ML1 is provided so as to be contiguous to two lower electrodes LE1 adjacent to each other, the upper electrode UE1 can be formed so as to place one upper electrode UE1 on two lower electrodes LE1 adjacent to each other. This makes it possible to form two memory elements ME1 by using one upper electrode UE1.

The upper electrode UE1 contains, for example, a third metal material. Examples of the third metal material include W, Ta, Ti, and Ru, and alloys containing any two or more of them. The upper electrode containing such a material can actualize a memory element ME1 having excellent operation performance. Such an advantage becomes more marked when the memory element ME1 is a resistance variable element. The upper electrode UE1 may contain an oxide or nitride of the above-mentioned first metal material.

The upper electrode UE1 has a thickness of for example, 5 nm or more but not more than 100 nm. By adjusting the thickness of the upper electrode UE1 to the lower limit or more, the upper electrode UE1 can be functioned fully as an electrode configuring the memory element. On the other hand, by adjusting the thickness of the upper electrode UE1 to the upper limit or less, the processing property upon patterning can be improved. In addition, since the upper electrode UE1 can be thinned fully, it can contribute to improvement in filling, with an interlayer insulating film, a step difference generated between the memory element formation region and another region. This enables manufacture of a more stable semiconductor device.

As shown in FIG. 2, the lower electrode LE1, the middle layer ML1, and the upper electrode UE1 are provided so that, for example, at least a portion of the layered region LR1 overlaps, in plan view, with the gate electrode GE1 configuring the transistor TR1 which is coupled to the lower electrode LE1. Even if the layered region LR1 is shifted so as not to overlap with the plug PR1, an increase in the area of the semiconductor device SE1 can be suppressed. This contributes to downsizing of the semiconductor device SE1 while reducing variation in the characteristics of the semiconductor device SE1. The layered region LR1 does not necessarily overlap with the gate electrode GE1.

The upper electrode UE1 has thereon, for example, an insulating layer IL2. In the example shown in FIG. 1, the upper electrode UE1 and the insulating layer IL1 have thereon the insulating layer IL2. The insulating layer IL2 is made of, for example, SiN, SiON, or SiCN. The insulating layer 1L2 has thereon an interlayer insulating film II2. The interlayer insulating film II2 is made of, for example, SiO₂ or SiOC.

The interlayer insulating film II2 has therein, for example, plugs PR2. The plugs PR2 are provided so as to penetrate, for example, the interlayer insulating film II2 and the insulating layer IL2. Some of the plugs PR2 are provided on the upper electrode UE1 and are coupled to the upper electrode UE1. A voltage is therefore applied to the upper electrode UE1 via the plugs PR2. Some of the other plugs PR2, among the plugs PR2, are coupled to, for example, the plug PR1.

The plugs PR2 are made of, for example, W or Cu. In the present embodiment, the plugs PR2 can each be formed, for example, by successively stacking, in a via hole formed in the interlayer insulating film II2, a barrier metal film and a conductive film made of W or Cu. As the barrier metal film, for example, Ti or TiN, or a stacked film thereof, or Ta or TaN, or a stacked film thereof can be used. When the plugs PR2 are each made of Cu, the plugs PR2 can be formed using, for example, damascene process.

The interlayer insulating film II2 has thereon, for example, an interlayer insulating film II3. The interlayer insulating film II3 is made of, for example, SiO₂ or SiOC. The interlayer insulating film II3 has therein, for example, a wiring IC1. The wiring IC1 is provided so that at least a portion thereof is coupled to the plug PR2. The wiring IC1 is made of, for example, Cu, Al, or W. In the present embodiment, the wiring IC1 can be comprised of a Cu wiring formed, for example, by damascene process.

In FIG. 1, the structure on the interlayer insulating film II3 is omitted from the multilayer wiring structure configuring the semiconductor device SE1. The interlayer insulating film II3 has thereon a plurality of wiring layers including an interlayer insulating film and a wiring. The multilayer wiring structure has, on the uppermost portion thereof, for example, an electrode pad configuring an external terminal.

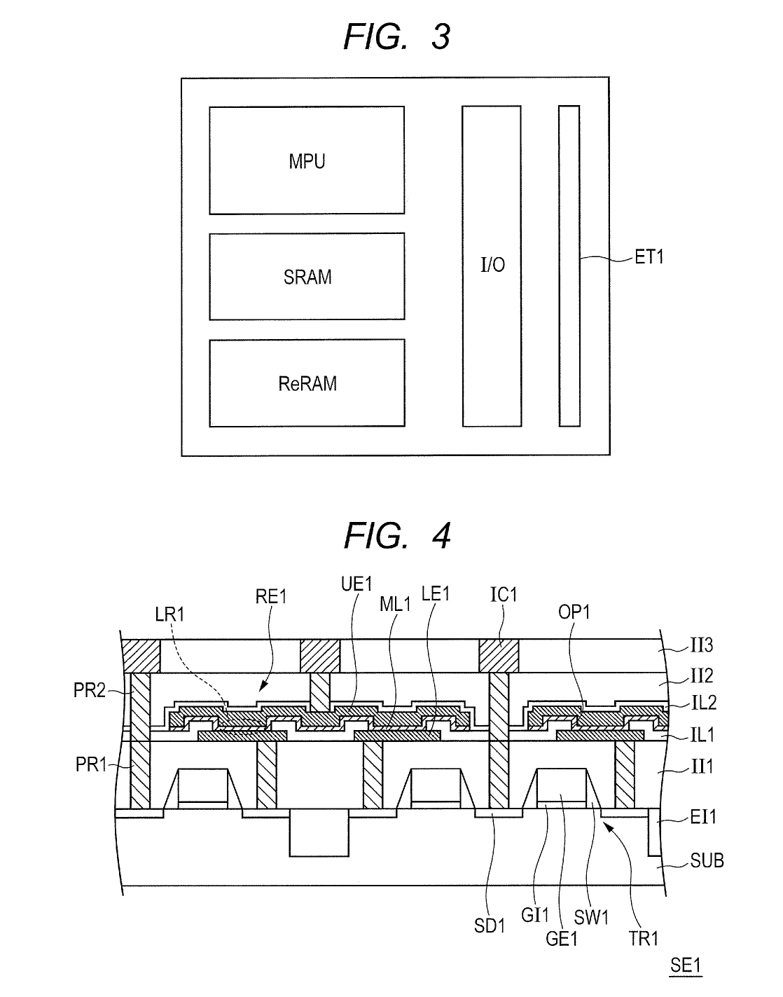

FIG. 3 is a schematic plan view showing the semiconductor device SE1 according to the present embodiment and schematically describes a circuit and the like included in the semiconductor device SE1. FIG. 3 shows a microcontroller as an example of the semiconductor device SE1. A microcontroller as the semiconductor device SE1 is provided with, for example, MPU (micro processing unit), SRAM (static random access memory), ReRAM, I/O circuit, and external terminal ET1. Of these, as the ReRAM, the memory element ME1 comprised of the lower electrode LE1, the middle layer ML1, and the upper electrode UE1 can be used. The I/O circuit is coupled to the external terminal ET1. The external terminal ET1 is, for example, an electrode pad provided on the chip surface. The semiconductor device SE1 shown in FIG. 3 may include a circuit other than the above-mentioned circuit.

The semiconductor device SE1 does not have a wiring, for example, in a layer having therein the lower electrode LE1. The wiring configures, for example, a logic circuit. The semiconductor device SE1 shown in FIG. 3 can adopt a configuration which does not have, in a layer having therein the lower electrode LE1, a wiring that configures a circuit of MPU or SRAM. In such a configuration, the lower electrode LE1 can be formed discretely from another wiring and therefore can contribute to improvement in operation performance of the memory element ME1.

The semiconductor device SE1 is equipped with, for example, the transistor TR1 (first transistor) to which the lower electrode LE1 is coupled and a transistor (second transistor) having a gate insulating film thinner than that of the transistor TR1. The transistor TR1, which is a first transistor, is a cell transistor that configures, together with the memory element ME1, a memory cell. The second transistor is, for example, a transistor used in a logic circuit in the semiconductor device SE1. In the example shown in FIG. 3, for example, a transistor configuring a SRAM can be given as one example of the second transistor.

In such a configuration, the transistor TR1 can have a gate insulating film thicker than that of the second transistor and has a structure similar to that of an I/O transistor to be coupled to the external terminal ET1. In this case, the transistor TR1 has a gate insulating film substantially as thick as the I/O transistor. By using the I/O transistor as the transistor TR1, formation of a cell transistor to be coupled to the memory element ME1 becomes unnecessary. This leads to a reduction in the number of manufacturing steps and further, facilitates thickening the gate insulating film GI1 and thereby increasing the breakdown voltage of the transistor TR1. As a result, operations such as forming operation can be carried out more stably. Further, the I/O transistor has often a gate length longer than that of the second transistor. Even when the layered region LR1 is shifted from a position overlapping with the plug PR1, an increase in area of the whole memory cell can be suppressed.

In the example shown in FIG. 1 and FIG. 2, the lower electrode LE1, the middle layer ML1, and the upper electrode UE1 are provided so as to prevent the layered region LR1 from overlapping with the plug PR1 in plan view. This surely reduces the influence of irregularities due to the plug PR1 on the layered region LR1, making it possible to effectively suppressing the semiconductor device SE1 from having variation in characteristics.

When as shown in FIG. 2, the layered region LR1 does not overlap with the plug PR1 in plan view, the minimum distance Dₘᵢₙ between the layered region LR1 and the plug PR1 in a plane direction parallel to the plane of the substrate SUB is not particularly limited. It can however be set at, for example, 10 nm or more but not more than 500 nm. This makes it possible to provide the semiconductor device SE1 in reduced size while surely suppressing the middle layer ML1 from being affected by the irregularities attributable to the plug PR1.

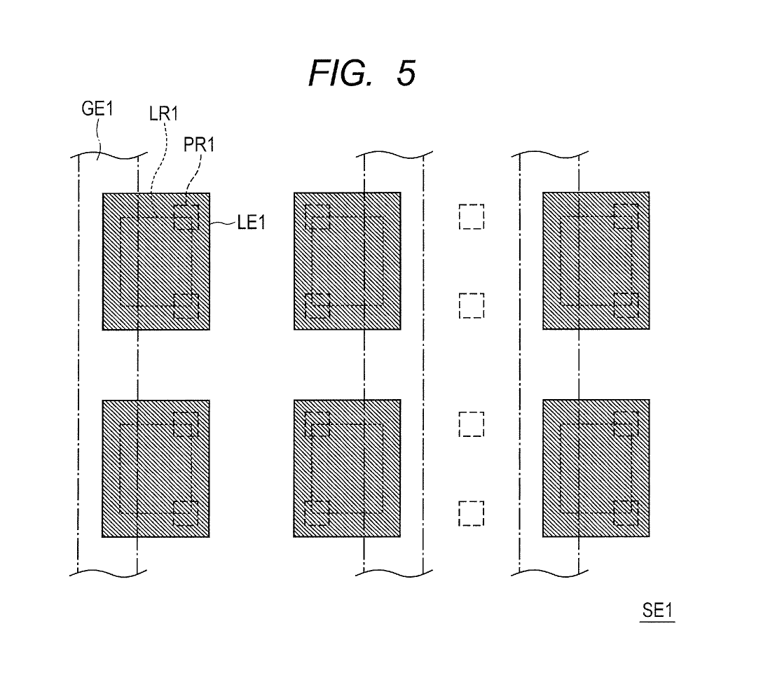

FIG. 4 is a cross-sectional view showing a modification example of the semiconductor device SE1 shown in FIG. 1. FIG. 5 is a plan view showing the semiconductor device SE1 shown in FIG. 4. FIG. 5 shows the positional relationship among the lower electrode LE1, the layered region LR1, the plug PR1, and the gate electrode GE1.

FIGS. 4 and 5 show the case where the lower electrode LE1, the middle layer ML1, and the upper electrode UE1a are provided so that a portion of the layered region LR1 overlaps with a portion of the plug PR1 in plan view. In this case, the lower electrode LE1, the middle layer ML1, and the upper electrode UE1 are provided so that the other portion of the layered region LR1 does not overlap with the plug PR1 and the other portion of the plug PR1 does not overlap with the layered region LR1. Also in this modification example, the influence that the layered region LR1 receives from the irregularities attributable to the plug PR1 can be reduced compared with the case where the whole layered region LR1 overlaps with the plug PR1 or the whole plug PR1 overlaps with the layered region LR1. In addition, by overlapping a portion of the layered region LR1 with a portion of the plug PR1, the semiconductor device SE1 thus obtained has an area more effectively suppressed from increasing. Further, since overlapping of the layered region LR1 with the plug PR1 is allowed, it becomes easy to increase the area of the layered region LR1 and thereby stabilize the operation performance of the memory element ME1.

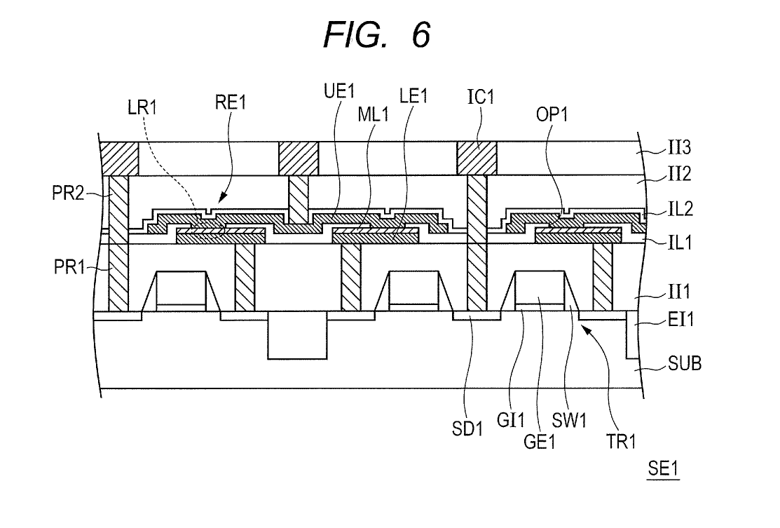

FIG. 6 is a cross-sectional view showing a modification example of the semiconductor device SE1 shown in FIG. 1 and the example shown in it is different from that shown in FIGS. 4 and 5. FIG. 6 shows the case where the middle layer ML1 is provided so as to be contiguous to the lower electrode LE1 also in a region overlapping with the plug PR1. The middle layer ML1 is provided so as to be brought into contact with the whole upper surface of the lower electrode LE1. Also in this modification example, for example, the lower electrode LE1 and the middle layer ML1 can be formed so as to have the same shape. Since the lower electrode LE1 and the middle layer ML1 can be processed simultaneously, the number of manufacturing steps can be reduced.

In the present modification example, the interlayer insulating film II1 and the middle layer ML1 have thereon an insulating layer IL1 having an opening portion OP1 which exposes, at the lower end thereof, the middle layer ML1. The upper electrode UE1 is contiguous to the middle layer ML1 in the opening portion OP1. The layered region LR1 of the middle layer ML1 is therefore provided only below the opening portion OP1.

Next, a method of manufacturing the semiconductor device SE1 will be described.

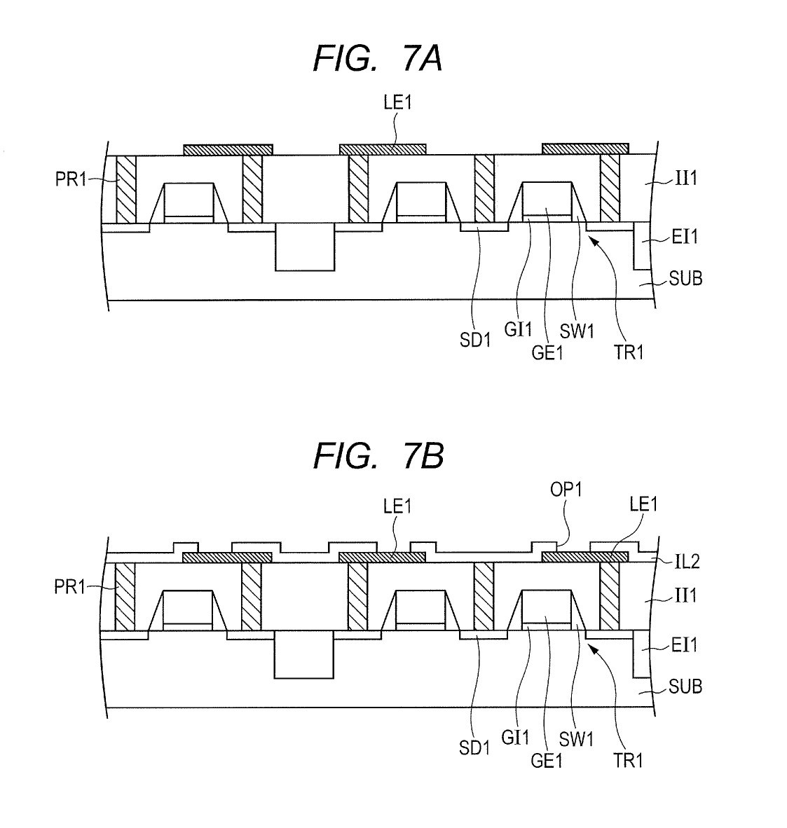

FIGS. 7A and 7B to 9A and 9B are cross-sectional views showing a method of manufacturing the semiconductor device SE1 shown in FIG. 1. First, an element isolation region EI1 is formed in a substrate SUB. Although the structure of the element isolation region EI1 is not particularly limited, this region can have an STI (shallow trench isolation) structure. Next, a transistor TR1 is formed on the substrate SUB.

The transistor TR1 is formed, for example, as follows.

First, a gate insulating film GI1 and a gate electrode GE1 are formed successively on the substrate SUB. The gate insulating film GI1 and the gate electrode GE1 are formed, for example, by successively stacking a silicon oxide film and a polycrystalline silicon film on the substrate SUB and then patterning them by dry etching. Then, a sidewall SW1 is formed on the side walls of the gate electrode GE1. Next, a source•drain region SD1 is formed by introducing impurities into the substrate SUB by ion implantation while using the gate electrode GE1 and the sidewall SW1 as a mask.

Next, an interlayer insulating film II1 is formed on the substrate SUB so as to cover the transistor TR1. The interlayer insulating film Ill is formed, for example, by depositing an insulating film on the substrate SUB and then planarizing it by CMP (chemical mechanical deposition) or the like. Next, a plug PR1 to be coupled to the source-drain region SD1 is formed in the interlayer insulating film II1. The plug PR1 is formed, for example, by depositing W in the contact hole provided in the interlayer insulating film II1 and on the interlayer insulating film II1 and then removing W deposited outside the contact hole by CMP.

Next, at least the upper surface of the plug PR1 is subjected to plasma processing with Ar. This makes it possible to remove the oxide film on the upper surface of the plug PR1 and thereby improve the coupling reliability between the plug PR1 and the lower electrode LE1.

Next, a lower electrode LE1 to be coupled to the plug PR1 is formed on the interlayer insulating film II1 and on the plug PR1. The lower electrode LE1 can be obtained, for example, by patterning a conductive film formed by sputtering or CVD (chemical vapor deposition) on the interlayer insulating film II1. The lower electrode LE1 excellent in surface flatness can therefore be obtained. Patterning of the conductive film is performed, for example, by dry etching with a resist mask formed by lithography. As a result, the structure shown in FIG. 7A can be obtained.

Next, an insulating layer IL1 is formed on the interlayer insulating film II1 and the lower electrode LE1. The insulating layer IL1 is formed, for example, by CVD. Next, the insulating layer IL1 is patterned to form an opening portion OP1 exposing, at the lower end thereof, the lower electrode LE1 therefrom. The patterning of the insulating layer IL1 is performed so as to prevent at least a portion of the opening portion OP1 from overlapping with the plug PR1 in plan view and prevent at least a portion of the plug PR1 from overlapping with the opening portion OP1 in plan view. In addition, the patterning of the insulating layer IL1 is performed, for example, by dry etching with a resist mask formed by lithography.

As a result, the structure shown in FIG. 7B can be obtained.

Next, a middle layer ML1 and an upper electrode UE1 are formed successively on the insulating layer IL1. The middle layer ML1 is formed so as to be contiguous to the lower electrode LE1 at the opening portion OP1.

In the present embodiment, the middle layer ML1 and the upper electrode UE1 can be formed, for example, as follows. First, a metal oxide film configuring the middle layer ML1 is formed on the insulating layer IL1 and on the lower electrode LE1 exposed from the opening portion OP1. The metal oxide film is formed, for example, by sputtering or CVD. The metal oxide film may be formed, for example, by forming a metal film and then subjecting the resulting metal film to plasma oxidation treatment or thermal oxidation treatment. Next, a conductive film for configuring an upper electrode UE1 is formed on the metal oxide film. The conductive film is formed, for example, by sputtering or CVD. Next, the metal oxide film and the conductive film are patterned simultaneously to form the middle layer ML1 and the upper electrode UE1 stacked successively. In this case, the middle layer ML1 and the upper electrode UE1 have the same shape in plan view. The metal oxide film and the conductive film are patterned, for example, dry etching with a resist mask formed by lithography.

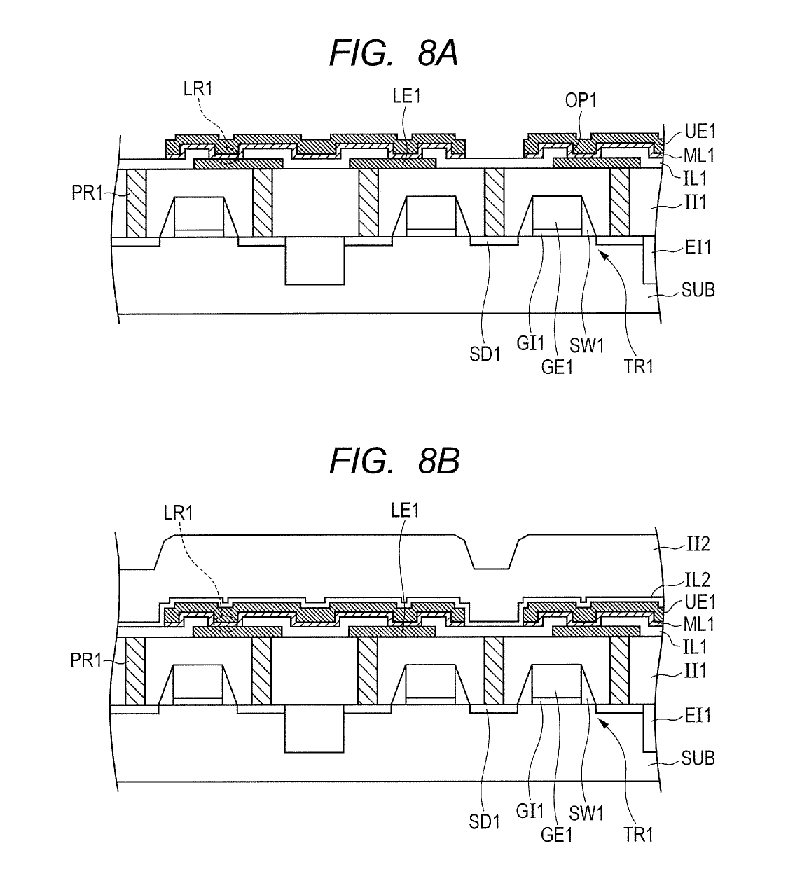

As a result, the structure as shown in FIG. 8A is formed.

Next, an insulating layer IL2 is formed on the upper electrode UE1. The insulating layer IL2 is formed on the upper electrode UE1 and the insulating layer IL1, for example, by CVD. Next, an interlayer insulating film II2 is deposited on the insulating layer IL2. Deposition of the interlayer insulating film II2 is performed, for example, by CVD. As a result, the structure shown in FIG. 8B can be obtained.

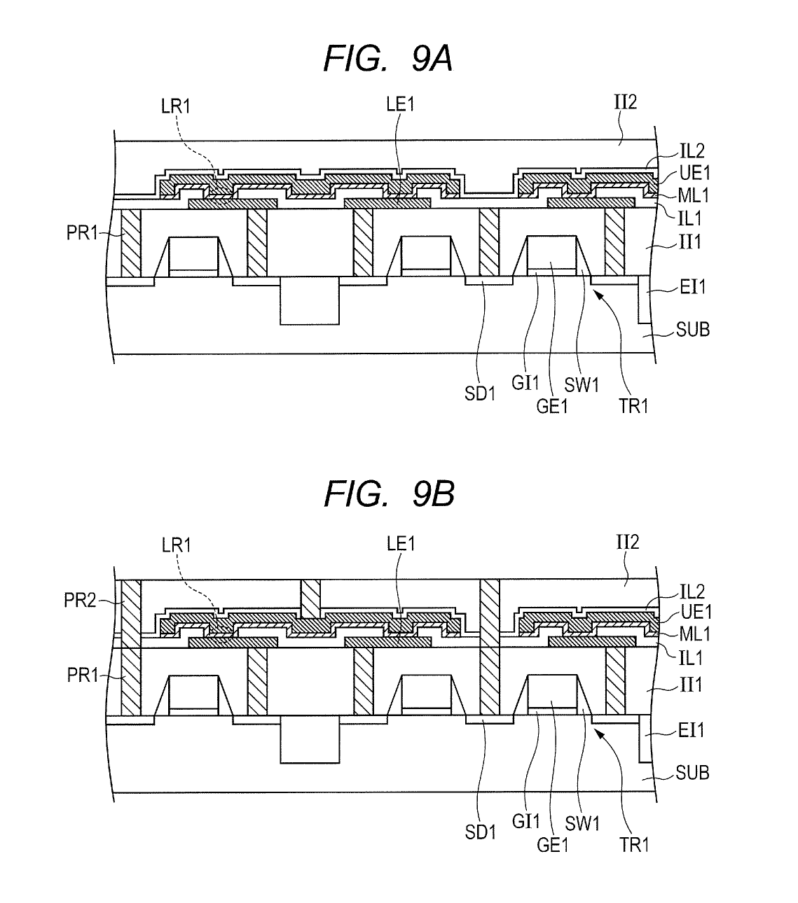

Next, the interlayer insulating film II2 is planarized by CMP or the like. As a result, the structure shown in FIG. 9A can be obtained.

Next, via holes penetrating the interlayer insulating film II2 and the insulating layer IL2 are formed. In the present embodiment, a plurality of via holes is formed so that some via holes are coupled to the upper electrode UE1 and the other via holes are coupled to the plug PR1. Next, a plug PR2 is formed in the via holes. The plug PR2 can be formed, for example, by successively depositing a barrier metal film and a conductive film made of W or Cu in the via holes and on the interlayer insulating film II2 and then removing by CMP the barrier metal film and the conductive film located outside the via holes.

As a result, the structure shown in FIG. 9B can be obtained.

Next, an interlayer insulating film II3 is formed on the interlayer insulating film II2. Next, wirings IC1 are formed in the interlayer insulating film II3. The wirings IC1 are formed so that at least some of them are coupled to the plug PR2. The wirings IC1 can be formed, for example, by a damascene process. In this case, the wirings IC1 are formed by depositing a Cu film in an opening portion formed in the interlayer insulating film II1 by using a plating method.

Then, a plurality of wiring layers comprised of, for example, an interlayer insulating film and a wiring is formed on the interlayer insulating film II3. As a result, a multilayer wiring structure is formed. In the present embodiment, the semiconductor device SE1 shown in FIG. 1 is manufactured, for example, in the above-mentioned manner.

### Second Embodiment

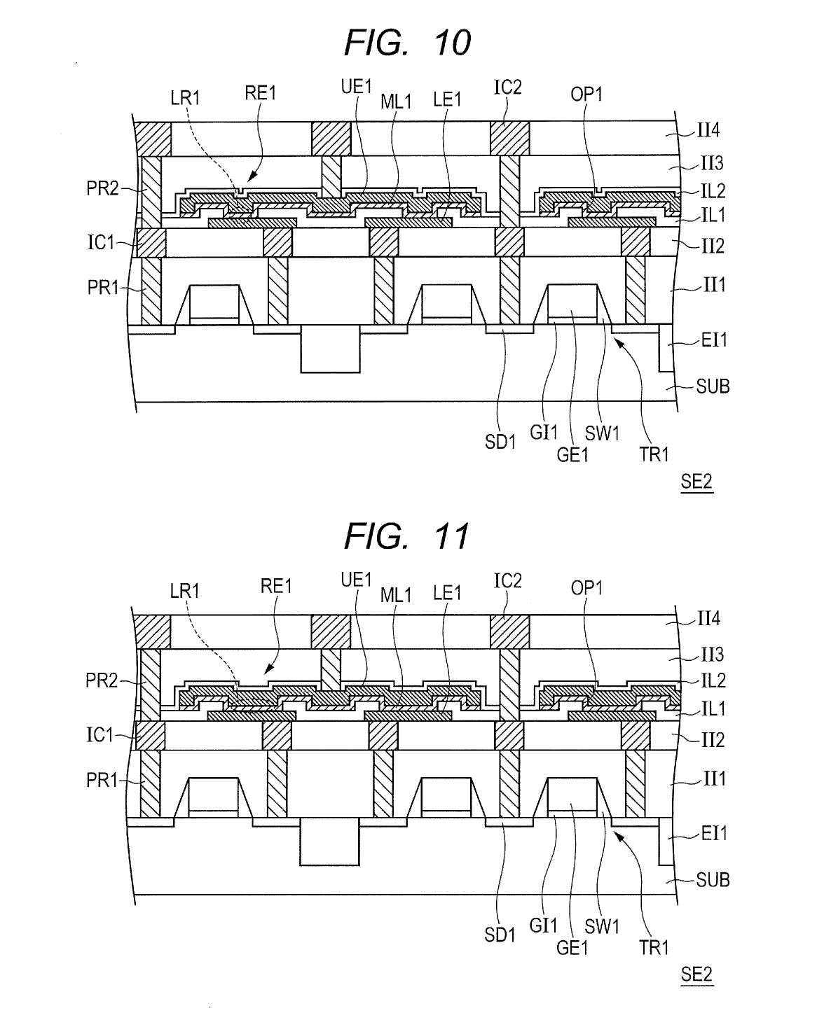

FIG. 10 is a cross-sectional view showing a semiconductor device SE2 according to a second embodiment and corresponds to FIG. 1 in First Embodiment. The semiconductor device SE2 is different from the semiconductor device SE1 in that a memory element ME1 is provided on a wiring layer having therein a wiring IC1.

The semiconductor device SE2 according to Second Embodiment is equipped with a wiring 101 extending in a first direction, a lower electrode LE1, a middle layer ML1, and an upper electrode UE1. The lower electrode LE1 is provided on the wiring IC1 and is coupled to the wiring IC1. The middle layer ML1 is provided on the lower electrode LE1 and is made of a metal oxide. The upper electrode UE1 is provided on the middle layer ML1. The middle layer ML1 has a layered region LR1 contiguous to the lower electrode LE1 and the upper electrode UE1. The layered region LR1 does not overlap with at least one side of the wiring IC1 and at least a portion of the layered region does not overlap with the wiring 101.

The term “the layered region LR1 does not overlap with at least one side of the wiring IC1” means that it does not overlap with at least one side of two sides which the wiring IC1 extending in the first direction has and are parallel to the first direction. This term therefore embraces the case where the layered region overlaps with one side of two sides parallel to the first direction and does not overlap with the other side; and the case where the layered region overlaps with neither one of two sides parallel to the first direction.

As described above, when the MIM structure configuring a memory element has therebelow wirings, the thickness of a middle layer may become uneven due to irregularities attributable to the wirings. Examples of the irregularities attributable to the wirings include voids generated due to burying failure of a metal material or corrosion of the wiring surface or hillocks generated due to corrosion of the wiring surface. Although their reduction is tried by controlling a queue time limit (Q-time) from completion of the previous step to the initiation of the next step or the like, but it is sometimes difficult to completely eliminate them. Particularly in Cu wirings, a step difference may occur between a barrier metal film and the Cu film due to a difference in removal rate between the barrier metal film and the Cu film. There is therefore a demand for reduction of the influence of irregularities attributable to such wirings on the MIM structure.

In the semiconductor device SE2 according to the present embodiment, the layered region LR1 does not overlap with at least one side of the wiring IC1 and at least a portion of the layered region does not overlap with the wiring 101. This means that the layered region LR1 of the middle layer ML1 which will configure the memory element ME1 is formed so that the plane position of it is shifted from a position overlapping with the wiring IC1. This makes it possible to reduce the influence of the irregularities attributable to the wiring IC1 on the layered region LR1 compared with the case where the whole layered region LR1 overlaps with the wiring IC1 or the layered region LR1 overlaps with both sides of the wiring IC1. As a result, the middle layer ML1 in the layered region LR1 can have improved uniform thickness. According to the present embodiment, therefore, the semiconductor device SE1 thus manufactured can have less variation in characteristics.

In the semiconductor device SE2 according to the present embodiment, as shown in FIG. 10, the memory element ME1 can be formed in a layer having therein a via plug for coupling between wiring layers. This suppresses an increase in a distance between the substrate SUB and a first-layer wiring (M1 wiring) formed on the substrate SUB or a distance between two wiring layers adjacent to each other due to formation of the memory element ME1. The operation rate in a circuit region other than the circuit region where the memory element ME1 is provided can therefore be improved. Further, the operation rate in the other circuit region can be made equal to the operation rate of a semiconductor device having no memory element ME1. This can enhance the compatibility in circuit design between semiconductor devices having the memory element ME1 and not.

In addition, coupling between a contact plug and a via plug or coupling between a via plug and a via plug due to the formation of the memory element ME1 can be prevented. As a result, variation in parameter such as resistance or capacitance due to coupling between plugs can be reduced.

The configuration of the semiconductor device SE2 will next be described in detail.

The substrate SUB, the transistor TR1, the interlayer insulating film II1, and the plug PR1 can have, for example, configurations similar to those of First Embodiment. Similar to First Embodiment, the semiconductor device SE1 may be equipped with a second transistor having a gate insulating film thinner than that of the transistor TR1 (first transistor).

In the semiconductor device SE2 according to the present embodiment, the memory element ME1 is provided on the wiring layer having therein the wiring IC1. The wiring IC1 is made of, for example, a polycrystal composed mainly of Cu. In this case, the wiring IC1 is formed in the interlayer insulating film II2 by using, for example, a damascene process. The wiring IC1 may be made of Al, W, or the like.

FIG. 10 shows the wiring IC1 provided in the interlayer insulating film II2 formed on the interlayer insulating film II2. The interlayer insulating film Ill and the interlayer insulating film II2 having therein the wiring IC1 may further have, between them, one or more other wiring layers each comprised of an interlayer insulating film and a wiring.

The lower electrode LE1 is provided on the interlayer insulating film II2 and the wiring IC1 so as to be coupled to the wiring IC1. Except for it, the lower electrode LE1 can be formed so as to have, for example, a configuration similar to that of the first embodiment. This means that the lower electrode LE1 contains, for example, the first metal material exemplified in the first embodiment.

On the interlayer insulating film II2 and on the lower electrode LE1, an insulating layer IL1 having an opening portion OP1 exposing at the lower end thereof the lower electrode LE1 is formed. The middle layer ML1 is therefore contiguous to the lower electrode LE1 at the opening portion OP1 and has the layered region LR1 in the opening portion OP1. The opening portion OP1 can be formed so as not to overlap with at least one side of wiring IC1 and at least a portion of the opening portion does not overlap with the wiring IC1. Except for this point, the insulating layer IL1 can be formed so as to have, for example, a configuration similar to that of First Embodiment.

The middle layer ML1 is provided so that the layered region LR1 contiguous to the lower electrode LE1 and the upper electrode UE1 does not overlap with at least one side of the wiring IC1 and at least a portion of the layered region does not overlap with the wiring IC1. Such a configuration can be actualized by forming, for example, the opening portion OP1, in which the layered region LR1 is to be formed, as described above.

Except for it, the middle layer ML1 can be formed so as to have, for example, a configuration similar to that of First Embodiment. Described specifically, the middle layer ML1 contains the second metal material exemplified in First Embodiment which material is different from the first metal material. At least a portion of the layered region LR1 of the middle layer ML1 overlaps, for example, with a gate electrode GE1 configuring the transistor TR1.

The upper electrode UE1 can be formed, for example, so as to have a configuration similar to that of First Embodiment. Described specifically, the upper electrode UE1 can have, for example, the same shape as the middle layer ML1 in plan view. The upper electrode UE1 can have thereon, for example, an insulating layer IL2 as in first Embodiment.

The insulating layer IL2 has thereon an interlayer insulating film II3. The interlayer insulating film II3 has therein plugs PR2 penetrating the interlayer insulating film II3 and the insulating layer IL2. Some plugs PR2, among a plurality of the plugs PR2, are coupled to the upper electrode UE1 and the other plugs PR2 are coupled to the plug PR1. Except for this, the plugs PR2 can be formed as in First Embodiment.

The interlayer insulating film II3 has thereon an interlayer insulating film II4. The interlayer insulating film II4 is made of, for example, SiO₂ or SiOC. The interlayer insulating film II4 has therein, for example, wirings 102. At least some of the wirings 102, among a plurality of the wirings 102, are provided so as to be coupled to the plugs PR2. As the wirings 102, for example, a Cu wiring formed by a damascene process can be used. The wirings 102 may be made of W, Al, or the like. The interlayer insulating film II3 may have thereon a plurality of wiring layers each including an interlayer insulating film and a wiring as in First Embodiment (not illustrated).

In the example shown in FIG. 10, the lower electrode LE1, the middle layer ML1, and the upper electrode UE1 are provided so that the layered region LR1 does not overlap with the wiring IC1. The influence of irregularities attributable to the wiring IC1 that the layered region LR1 should receive can surely be reduced. The semiconductor device SE2 having effectively suppressed variation in characteristics can therefore be provided.

FIG. 11 is a cross-sectional view showing a modification example of the semiconductor device SE2 shown in FIG. 10.

FIG. 11 shows an example in which the layered region LR1 overlaps with one side of the wiring IC1 and partially overlaps with the wiring IC1. In this case, the layered region LR1 overlaps with one side of the two sides of the wiring IC1 extending in a first direction which are parallel to each other in the first direction, while it does not overlap with the other side. A portion of the layered region LR1 overlaps with the wiring IC1 but the other portion does not overlap with the wiring IC1. Also in this modification example, the influence of the irregularities attributable to the wiring IC1 on the layered region LR1 can be reduced, compared with the case where the whole layered region LR1 overlaps with the wiring IC1 or where the layered region LR1 overlaps with both sides of the wiring IC1. Further, by overlapping a portion of the layered region LR1 with a portion of the wiring IC1, an increase in the area of the semiconductor device SE2 can be effectively suppressed. Still further, overlapping between the layered region LR1 and the wiring IC1 is allowed, making it easy to increase the area of the layered region LR1 and thereby stabilize the operation performance of the memory element ME1.

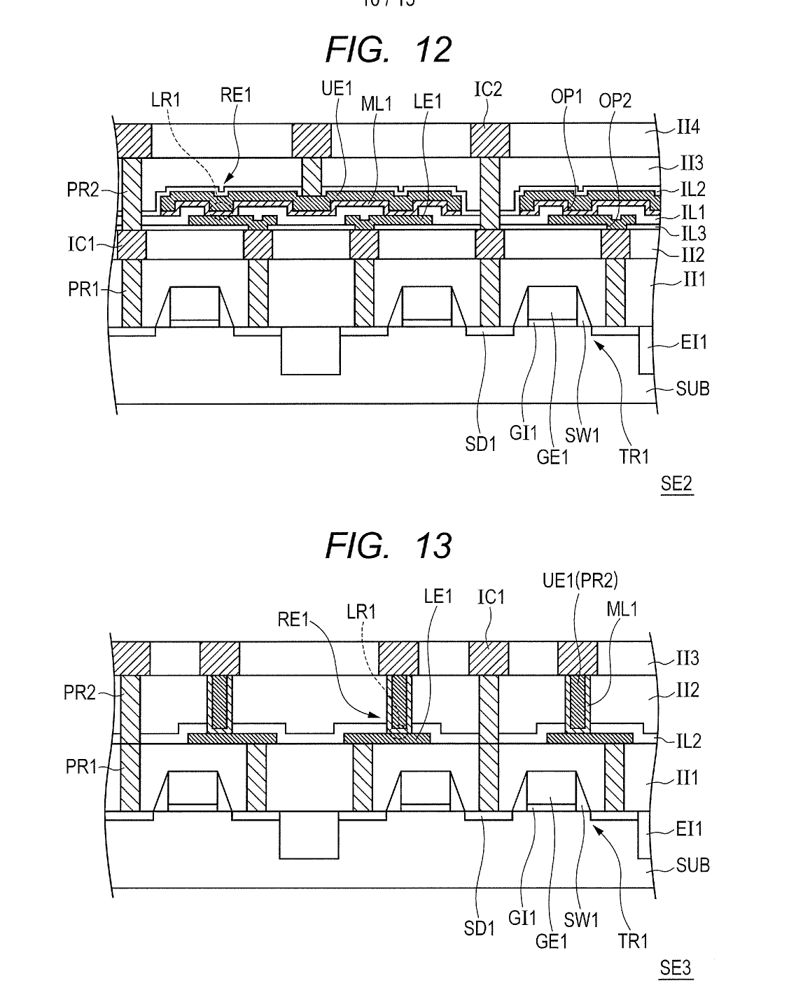

FIG. 12 is a cross-sectional view showing a modification example of the semiconductor device SE2 shown in FIG. 10 and shows an example different from that of FIG. 11. As shown in FIG. 12, the semiconductor device SE2 may be equipped further with an insulating layer IL3. The insulating layer IL3 is provided, for example, on the interlayer insulating film II2 and the wirings IC2. In other words, the insulating layer IL3 is provided below the lower electrode LE1 so as to cover the wiring IC1. Such a configuration can surely suppress the surface of the wiring IC1 from being corroded by a dry etching gas or the like during processing such as processing of the lower electrode LE1. Accordingly, the semiconductor device SE2 thus obtained can have improved reliability.

The insulating layer IL3 has an opening portion OP2 that exposes, at the lower end thereof, the wiring IC1. The lower electrode LE1 is therefore contiguous to the wiring IC1 at the opening portion OP2. As a result, a voltage can be supplied to the lower electrode LE1 via the wiring IC1.

A method of manufacturing the semiconductor device SE2 according to the present embodiment has a step of forming the interlayer insulating film II2 and the wiring IC1 after a step of forming the plug PR1 but before a step of forming the lower electrode LE1. Except for this, a method of manufacturing the semiconductor device SE2 can be performed as in the method for manufacturing the semiconductor device SE1 in First Embodiment.

The present embodiment can also have an advantage similar to that of First Embodiment.

### Third Embodiment

FIG. 13 is a cross-sectional view showing a semiconductor device SE3 according to Third Embodiment and corresponds to FIG. 1 in First Embodiment. The semiconductor device SE3 according to the present embodiment is similar to the semiconductor device SE1 according to First Embodiment except for the configuration of the middle layer ML1 and the upper electrode UE1.

The configuration of the semiconductor device SE3 according to the present embodiment and a method of manufacturing the semiconductor device SE3 will hereinafter be described specifically.

In the semiconductor device SE3 according to the present embodiment, the upper electrode UE1 is comprised of a plug PR2 formed in an interlayer insulating film II2. Since the upper electrode UE1 and the plug PR2 can therefore be formed simultaneously, the number of manufacturing steps can be reduced. FIG. 13 shows an example of forming, on the insulating layer IL2, the interlayer insulating film II2 having therein a plurality of the plugs PR2. Among these plugs PR2, some of the plugs PR2 located on the lower electrode LE1 are used as the upper electrode UE1.

The upper electrode UE1 is made of, for example, the same material as that of the plug PR2.

The middle layer ML1 is provided, for example, on the side surface and bottom surface of the plug PR2 configuring the upper electrode UE1. In other words, the middle layer ML1 is formed on the side surface and the bottom surface of a via hole formed in the interlayer insulating film II2 and filled with the upper electrode UE1. This enables processing of the middle layer ML1 together with the upper electrode UE1.

In the present embodiment, the middle layer ML1 is, at a portion thereof provided on the bottom surface of the upper electrode UE1, contiguous to the lower electrode LE1 and the upper electrode UE1 and has a layered region LR1.

Next, a method of manufacturing the semiconductor device SE3 will be described.

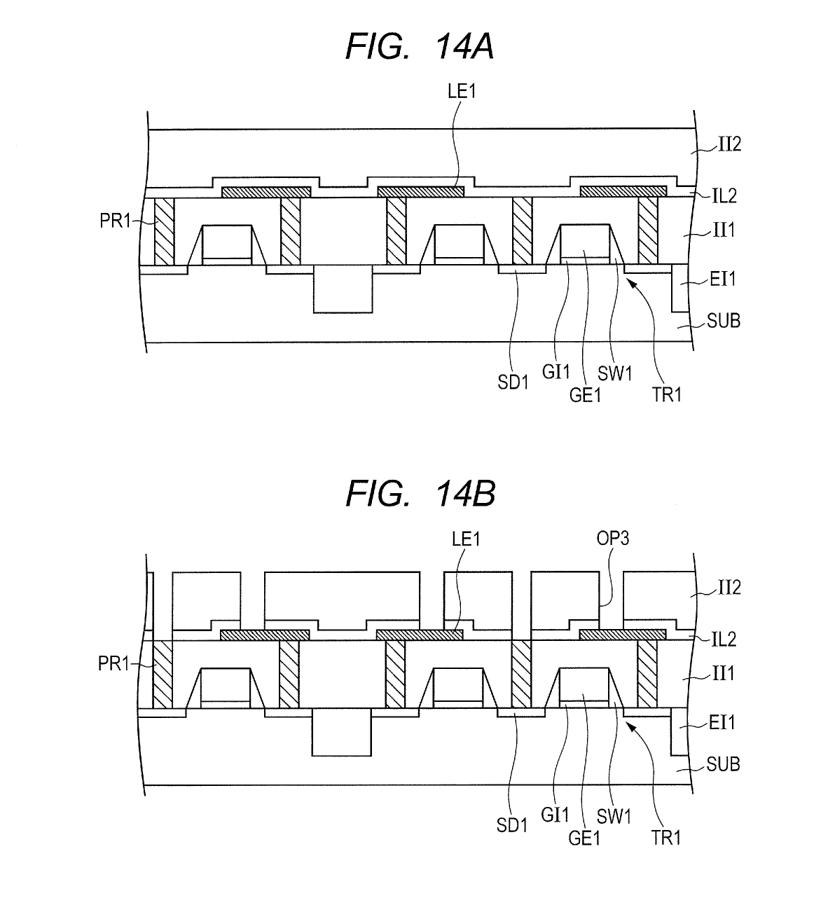

FIGS. 14A and 14B to 16A and 16B are cross-sectional views showing a method of manufacturing the semiconductor device SE3 shown in FIG. 13. First, an element isolation region EI1 and a transistor TE1 are formed in and on a substrate SUB. Then, an interlayer insulating film Ill is formed on the substrate SUB. Next, a plug PR1 is formed in the interlayer insulating film II1. Next, a lower electrode LE1 to be coupled to the plug PR1 is formed on the interlayer insulating film II1. Next, an insulating layer IL2 is formed on the lower electrode LE1. These steps can be carried out similarly to the manufacturing steps of the semiconductor device SE1 shown in FIGS. 7A AND 7B. Next, an interlayer insulating film II2 is formed on the insulating layer IL2. The interlayer insulating film II2 is formed, for example, by planarizing, by CMP or the like, an insulating film deposited by CVD.

As a result, the structure shown in FIG. 14A can be obtained.

Next, opening portions OP3 penetrating the interlayer insulating film II2 and the insulating layer IL2 are formed. In the present embodiment, a plurality of opening portions OP3 is formed so that some of the opening portions OP3 are coupled to the lower electrode LE1 and the other opening portions OP3 are coupled to the plug PR1.

As a result, the structure shown in FIG. 14B can be obtained.

Next, a metal oxide film MO1 configuring a middle layer ML1 is formed on the interlayer insulating film II2, the side surface of the opening portions OP3 and the bottom surface of the opening portions OP3. The metal oxide film MO1 is formed, for example, by CVD or ALD (atomic layer deposition).

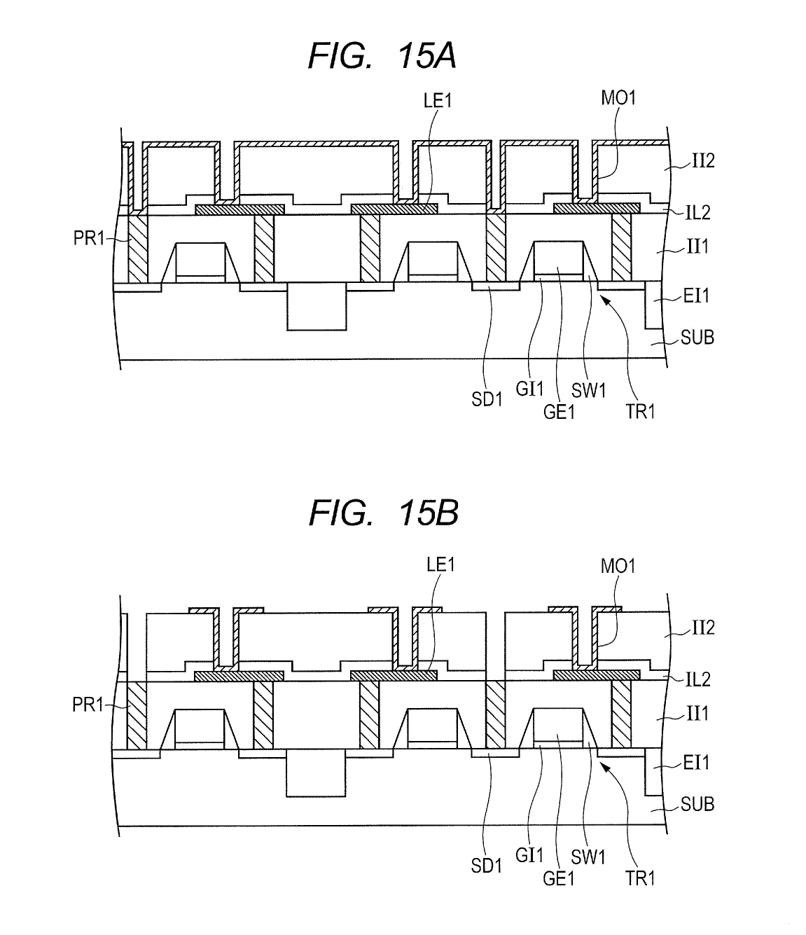

As a result, the structure shown in FIG. 15A can be obtained.

Next, the metal oxide film MO1 is selectively removed to leave a portion thereof on the side surface and the bottom surface of each of the opening portions OP3 formed on the lower electrode LE1. At this time, the metal oxide film MO1 may be removed so as to leave a portion of the metal oxide film MO1 formed on the interlayer insulating film II2 and located around each of the opening portions OP3 on the lower electrode LE1. This makes it possible to surely leave a portion of the metal oxide film MO1 located in the opening portions OP3. The metal oxide film MO1 is removed, for example, by dry etching with a resist mask formed by lithography.

As a result, the structure shown in FIG. 15B can be obtained.

Next, a barrier metal film (not illustrated) and a conductive film CF1 are deposited successively in each of the opening portions OP3 and on the interlayer insulating film II2. The conductive film CF1 is, for example, a W film. The barrier metal film and the conductive film CF1 are deposited, for example, by CVD.

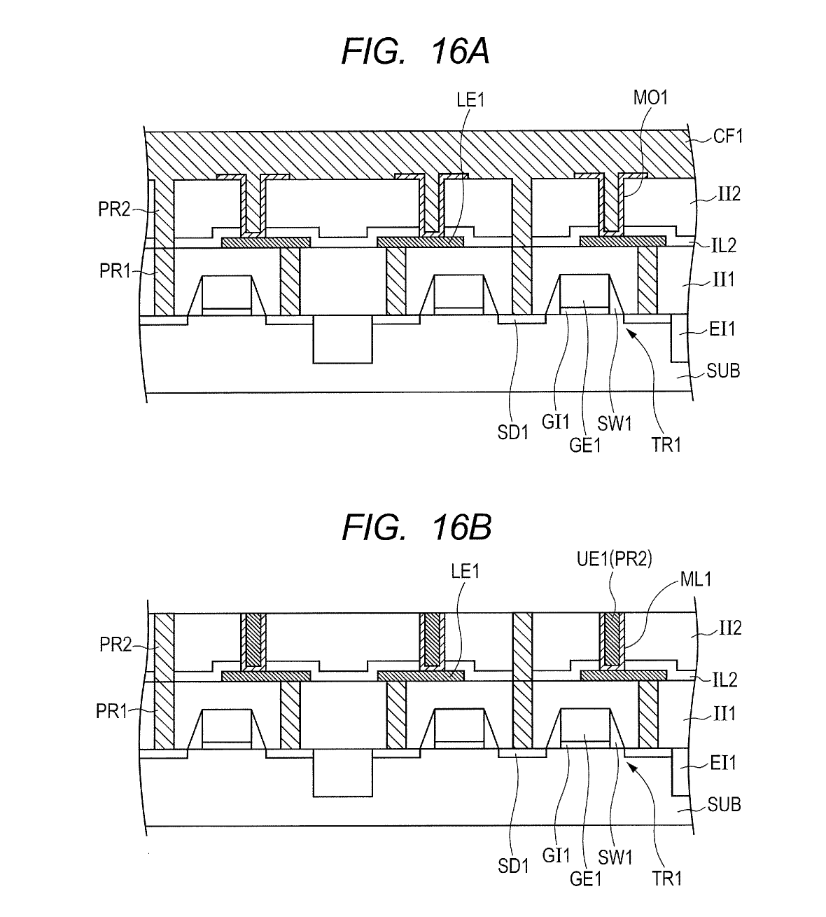

As a result, the structure shown in FIG. 16A can be obtained.

Next, the barrier metal film, the conductive film CF1, and the metal oxide film MO1 located outside the opening portions OP3 are removed by CMP. By this processing, the middle layer ML1 and the upper electrode UE1 are formed in each of the opening portions OP3 located on the lower electrode LE1, while the plugs PR2 are formed in each of the other opening portions OP3.

As a result, the structure shown in FIG. 16B can be obtained.

Then, an interlayer insulating film II3 and the wirings IC2 are formed on the interlayer insulating film II2. This step can be carried out as in First Embodiment. In the present embodiment, the semiconductor device SE3 shown in FIG. 13 can be manufactured, for example, in such a manner.

The present embodiment can also have an advantage similar to that of First Embodiment.

### Fourth Embodiment

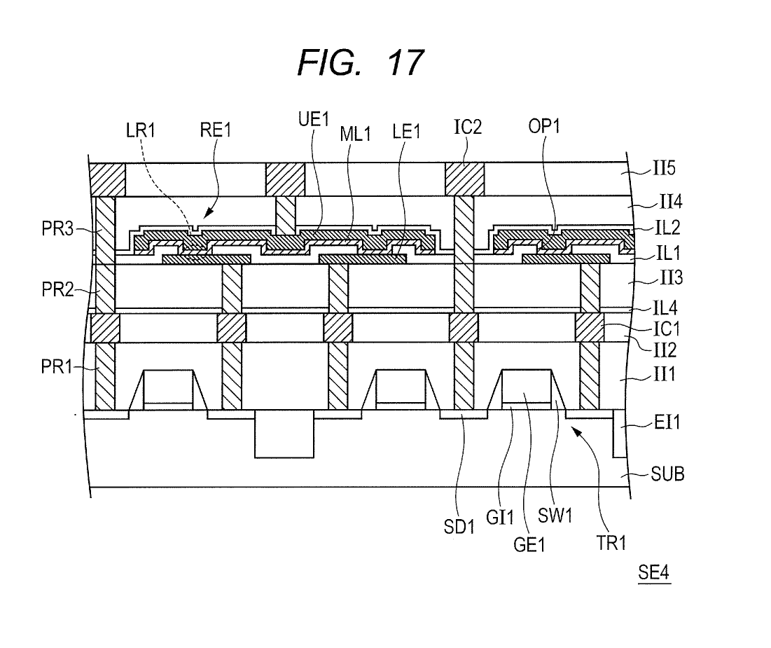

FIG. 17 is a cross-sectional view showing a semiconductor device SE4 according to Fourth Embodiment and it corresponds to FIG. 1 in First Embodiment. The semiconductor device SE4 has plugs PR2 above a wiring IC1 (M1 wiring) provided in a first-layer wiring on a substrate SUB and these plugs have thereon a memory element ME1. In the present embodiment, therefore, a lower electrode LE1, a middle layer ML1, and an upper electrode UE1 are provided so that at least a portion of a layered region LR1 does not overlap with each of the plugs PR2 and a portion of each of the plugs PR2 does not overlap with the layered region LR.

The configuration of the semiconductor device SE4 will hereinafter be described in detail.

In the example shown in FIG. 17, an interlayer insulating film II2 formed on an interlayer insulating film II1 has therein the wiring IC1. At least a portion of the wiring IC1 is provided, for example, so as to be coupled to a plug PR1. The interlayer insulating film II2 and the wiring IC1 can have a configuration similar to that of the interlayer insulating film II3 and the wiring IC1 in First Embodiment, respectively. The substrate SUB, a transistor TR1, the interlayer insulating film II1, and the plug PR1 can have configurations similar to, for example, those in First Embodiment, respectively.

The interlayer insulating film II2 and the wiring IC1 have thereon an insulating layer 1L4 and an interlayer insulating film II3 which have been stacked successively. The insulating layer IL4 is made of, for example, SiC, SiCN, or SiN. The interlayer insulating film II3 is made of, for example, SiO₂ or SiOC. The interlayer insulating film II3 has therein plugs PR2 penetrating the interlayer insulating film II3 and the insulating layer 1L4. At least some plugs PR2 of a plurality of the plugs PR2 is coupled to the wiring IC1. The plugs PR2 are each comprised of a stacked film of, for example, a barrier metal film and a conductive film made of Cu or W.

The interlayer insulating film II2 having therein the wirings IC1 and the interlayer insulating film II3 having therein the plugs PR2 have therebetween one or more other wiring layers each comprised of an interlayer insulating film and a wiring.

The lower electrode LE1 is provided on the interlayer insulating film II3 and on the plugs PR2 and is coupled to the plugs PR2. The insulating layer IL1, the middle layer ML1, the upper electrode UE1, and the insulating layer IL2 are provided successively on the lower electrode LE1. The lower electrode LE1, the middle layer ML1, the upper electrode UE1, the insulating layer ILL and the insulating layer IL2 can each have a configuration, for example, similar to that of First Embodiment.

In the present embodiment, the lower electrode LE1, the middle layer ML1, and the upper electrode UE1 are provided so that at least a portion of the layered region LR1 does not overlap with the each of the plugs PR2 and at least a portion of each of the plugs PR2 does not overlap with the layered region LR1.

The insulating layer IL2 has thereon an interlayer insulating film II4. The interlayer insulating film II4 has therein a plug PR3 penetrating the interlayer insulating film II4 and the insulating layer IL2. The interlayer insulating film II4 and the plug PR3 can have configurations similar to those of the interlayer insulating film II2 and the plug PR2 in First Embodiment, respectively.

The interlayer insulating film II4 has thereon an interlayer insulating film II5 and a wiring 103. The interlayer insulating film II5 and the wiring 1C3 can have configurations similar to those of the interlayer insulating film II3 and the wiring IC1 in First Embodiment, respectively.

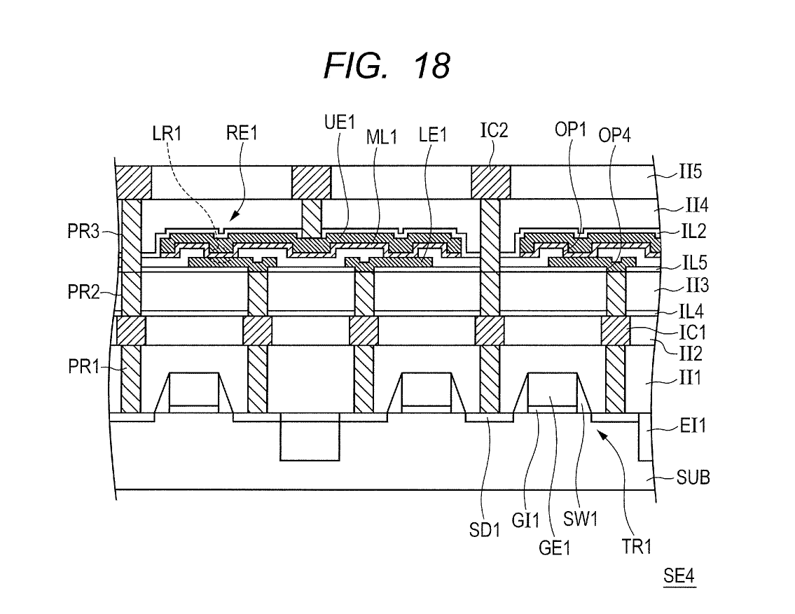

FIG. 18 is a cross-sectional view showing a modification example of the semiconductor device SE4 shown in FIG. 17.

As shown in FIG. 18, the semiconductor device SE4 may have an insulating layer IL5 further. The insulating layer IL5 is provided, for example, on the interlayer insulating film II3 and below the lower electrode LE1. This makes it possible to surely suppress the surface of the plug PR, which is not coupled to the lower electrode LE1, from being damaged upon processing of the lower electrode LE1. The semiconductor device SE4 thus obtained can therefore have improved reliability. The insulating layer IL5 is made of, for example, SiCN, SiN, or SiC. The insulating layer IL5 has an opening portion OP4 exposing, at the lower end thereof, the plug PR2. The lower electrode LE1 can therefore be brought into contact with the plug PR2 at the opening portion OP4.

The present embodiment can also produce an advantage similar to that of First Embodiment.

The invention made by the present inventors has been described specifically based on some embodiments. It is needless to say that the invention is not limited by these embodiments but can be changed in various ways without departing from the gist of the invention.

What is claimed is:

1. A semiconductor device, comprising:
a first plug formed in a first interlayer insulating film;
a lower electrode provided over the first plug and coupled to the first plug;
a middle layer provided over the lower electrode and has a metal oxide; and
an upper electrode provided over the middle layer,
wherein the middle layer has a layered region contiguous to the lower electrode and the upper electrode,
wherein at least a portion of the layered region does not overlap with the first plug, and
wherein at least a portion of the first plug does not overlap with the layered region.

2. The semiconductor device according to claim 1, further comprising:
an insulating layer provided over the lower electrode and having an opening portion exposing, at a lower end thereof, the lower electrode,
wherein the middle layer is contiguous to the lower electrode at the opening portion.

3. The semiconductor device according to claim 1,
wherein the upper electrode and the middle layer have the same shape in plan view.

4. The semiconductor device according to claim 1, further comprising:
a first transistor to be coupled to the lower electrode,
wherein at least a portion of the layered region overlaps with a gate electrode configuring the first transistor.

5. The semiconductor device according to claim 1, further comprising:
a first transistor to be coupled to the lower electrode and a second transistor having a gate insulating film thinner than that of the first transistor.

6. The semiconductor device according to claim 1,
wherein the layered region does not overlap with the first plug.

7. The semiconductor device according to claim 1,
wherein the lower electrode contains a first metal material, and
wherein the middle layer contains a second metal material different from the first metal material.

8. The semiconductor device according to claim 7,
wherein the first metal material is Ru, Pt, Ti, W, or Ta, or an alloy containing any two or more thereof.

9. The semiconductor device according to claim 1,
wherein the first plug has W.

10. The semiconductor device according to claim 1, further comprising:
a second interlayer insulating film provided over the lower electrode; and
a second plug formed in the second interlayer insulating film,
wherein the upper electrode has the second plug.

11. The semiconductor device according to claim 10,
wherein the middle layer is provided over the side surface and bottom surface of the second plug.

12. A semiconductor device, comprising:
a wiring extending in a first direction;
a lower electrode provided over the wiring and coupled to the wiring;
a middle layer provided over the lower electrode and having a metal oxide; and
an upper electrode provided over the middle layer,
wherein the middle layer has a layered region contiguous to the lower electrode and the upper electrode, and
wherein the layered region does not overlap with at least one side of the wiring and at least a portion of the layered region does not overlap with the wiring.

13. The semiconductor device according to claim 12, further comprising:
a first insulating layer provided over the lower electrode and having a first opening portion exposing, at a lower end thereof, the lower electrode,
wherein the middle layer is contiguous to the lower electrode at the first opening portion.

14. The semiconductor device according to claim 12,
wherein the upper electrode and the middle layer have the same shape in plan view.

15. The semiconductor device according to claim 12, further comprising:
a first transistor to be coupled to the lower electrode,
wherein at least a portion of the layered region overlaps with a gate electrode configuring the first transistor.

16. The semiconductor device according to claim 12, further comprising:
a first transistor to be coupled to the lower electrode and a second transistor having a gate insulating film thinner than that of the first transistor.

17. The semiconductor device according to claim 12,
wherein the layered region does not overlap with the wiring.

18. The semiconductor device according to claim 12, further comprising:
a second insulating layer provided below the lower electrode, covering the wiring, and provided with a second opening portion exposing, at a lower end thereof, the wiring,
wherein the lower electrode is contiguous to the wiring at the second opening portion.

19. The semiconductor device according to claim 12,
wherein the lower electrode contains a first metal material, and
wherein the middle layer contains a second metal material different from the first metal material.

20. The semiconductor device according to claim 12,
wherein the wiring has a polycrystal having Cu as a main component thereof.
